(19) United States
(12) Patent Application Publication
(10) Pub. No.: US 2015/0332970 A1
(43) Pub. Date: Nov. 19, 2015

(54) CARRIER WITH THERMALLY RESISTANT FILM FRAME FOR SUPPORTING WAFER DURING SINGULATION

(71) Applicants: Wei-Sheng Lei, San Jose, CA (US); Brad Eaton, Menlo Park, CA (US); Ajay Kumar, Cupertino, CA (US)

(72) Inventors: Wei-Sheng Lei, San Jose, CA (US); Brad Eaton, Menlo Park, CA (US); Ajay Kumar, Cupertino, CA (US)

(21) Appl. No.: 14/714,098

(22) Filed: May 15, 2015

Related U.S. Application Data
(62) Division of application No. 14/297,292, filed on Jun. 5, 2014, now abandoned.
(60) Provisional application No. 61/994,387, filed on May 16, 2014.

(51) Int. Cl. H01L 21/82; H01L 21/268; H01L 21/033; H01L 21/3065; H01L 21/683

(52) U.S. Cl. CPC H01L 21/82; H01L 21/3065; H01L 21/6836; H01L 21/0337; H01L 21/268; H01L 2221/68336

(57) ABSTRACT

Methods of and carriers for dicing semiconductor wafers, each wafer having a plurality of integrated circuits, are described. In an example, a carrier for supporting a wafer or substrate in an etch process includes a frame having a perimeter surrounding an inner opening. The frame is composed of a thermally resistant material. The carrier also includes a carrier tape coupled to the frame and disposed at least within the inner opening of the frame. The carrier tape includes a base film.

### CROSS-REFERENCE TO RELATED APPLICATIONS

This application is a divisional of U.S. patent application Ser. No. 14/297,292, filed on Jun. 5, 2014, which claims the benefit of U.S. Provisional Application No. 61/994,387, filed on May 16, 2014, the entire contents of which are hereby incorporated by reference herein.

### BACKGROUND

1) Field

Embodiments of the present invention pertain to the field of semiconductor processing and, in particular, to methods of and carriers for dicing semiconductor wafers, each wafer having a plurality of integrated circuits thereon.

2) Description of Related Art

In semiconductor wafer processing, integrated circuits are formed on a wafer (also referred to as a substrate) composed of silicon or other semiconductor material. In general, layers of various materials which are either semiconducting, conducting or insulating are utilized to form the integrated circuits. These materials are doped, deposited and etched using various well-known processes to form integrated circuits. Each wafer is processed to form a large number of individual regions containing integrated circuits known as dice.

Following the integrated circuit formation process, the wafer is “diced” to separate the individual die from one another for packaging or for use in an unpackaged form within larger circuits. The two main techniques that are used for wafer dicing are scribing and sawing. With scribing, a diamond tipped scribe is moved across the wafer surface along pre-formed scribe lines. These scribe lines extend along the spaces between the dice. These spaces are commonly referred to as “streets.” The diamond scribe forms shallow scratches in the wafer surface along the streets. Upon the application of pressure, such as with a roller, the wafer separates along the scribe lines. The breaks in the wafer follow the crystal lattice structure of the wafer substrate. Scribing can be used for wafers that are about 10 mils (thousandths of an inch) or less in thickness. For thicker wafers, sawing is presently the preferred method for dicing.

With sawing, a diamond tipped saw rotating at high revolutions per minute contacts the wafer surface and saws the wafer along the streets. The wafer is mounted on a supporting member such as an adhesive film stretched across a film frame and the saw is repeatedly applied to both the vertical and horizontal streets. One problem with either scribing or sawing is that chips and gouges can form along the severed edges of the dice. In addition, cracks can form and propagate from the edges of the dice into the substrate and render the integrated circuit inoperative. Chipping and cracking are particularly a problem with scribing because only one side of a square or rectangular die can be scribed in the <110>direction of the crystalline structure. Consequently, cleaving of the other side of the die results in a jagged separation line. Because of chipping and cracking, additional spacing is required between the dice on the wafer to prevent damage to the integrated circuits, e.g., the chips and cracks are maintained at a distance from the actual integrated circuits. As a result of the spacing requirements, not as many dice can be formed on a standard sized wafer and wafer real estate that could otherwise be used for circuitry is wasted. The use of a saw exacerbates the waste of real estate on a semiconductor wafer. The blade of the saw is approximate 15 microns thick. As such, to insure that cracking and other damage surrounding the cut made by the saw does not harm the integrated circuits, three to five hundred microns often must separate the circuitry of each of the dice. Furthermore, after cutting, each die requires substantial cleaning to remove particles and other contaminants that result from the sawing process.

Plasma dicing has also been used, but may have limitations as well. For example, one limitation hampering implementation of plasma dicing may be cost. A standard lithography operation for patterning resist may render implementation cost prohibitive. Another limitation possibly hampering implementation of plasma dicing is that plasma processing of commonly encountered metals (e.g., copper) in dicing along streets can create production issues or throughput limits.

### SUMMARY

Embodiments of the present invention include methods of, and apparatuses for, dicing semiconductor wafers.

In an embodiment, a carrier for supporting a wafer or substrate in an etch process includes a frame having a perimeter surrounding an inner opening. The frame is composed of a thermally resistant material. The carrier also includes a carrier tape coupled to the frame and disposed at least within the inner opening of the frame. The carrier tape includes a base film.

In another embodiment, a method of dicing a semiconductor wafer having a front surface with a plurality of integrated circuits involves providing the semiconductor wafer having a patterned mask covering the integrated circuits and having scribe lines between the integrated circuits. The method also involves plasma etching the semiconductor wafer through the scribe lines to singulate the integrated circuits. The semiconductor wafer is supported on a tape of a substrate carrier having a thermally resistant frame during the plasma etching.

In another embodiment, a method of dicing a semiconductor wafer having a front surface with a plurality of integrated circuits involves forming a mask on the front surface of the semiconductor wafer. The mask covers the integrated circuits and streets between the integrated circuits. The method also involves laser scribing the mask and streets to provide scribe lines between the integrated circuits and to leave a patterned mask covering the integrated circuits. The method also involves plasma etching the semiconductor wafer through the scribe lines to singulate the integrated circuits. The semiconductor wafer is supported on a tape of a substrate carrier having a thermally resistant frame during the plasma etching.

### BRIEF DESCRIPTION OF THE DRAWINGS

FIG. 1 illustrates a top plan of a semiconductor wafer to be diced, in accordance with an embodiment of the present invention.

FIG. 2 illustrates a top plan of a semiconductor wafer to be diced that has a dicing mask formed thereon, in accordance with an embodiment of the present invention.

FIG. 3 illustrates a plan view of a substrate carrier suitable for supporting a wafer during a singulation process, in accordance with an embodiment of the present invention.

FIG. 4A illustrates a cross-sectional view of a carrier tape, in accordance with an embodiment of the present invention.

FIG. 4B illustrates a plan view and corresponding cross-sectional view of (a) a film frame, and (b) a wafer and carrier assembly, in accordance with an embodiment of the present invention.

FIG. 4C includes equations and material properties for determining a suitable thermally resistant material for a film frame of a substrate carrier, in accordance with an embodiment of the present invention.

FIG. 5 is a Flowchart representing operations in a method of dicing a semiconductor wafer including a plurality of integrated circuits, in accordance with an embodiment of the present invention.

FIG. 6A illustrates a cross-sectional view of a semiconductor wafer including a plurality of integrated circuits during performing of a method of dicing the semiconductor wafer, corresponding to operation 502 of the Flowchart of FIG. 5, in accordance with an embodiment of the present invention.

FIG. 6B illustrates a cross-sectional view of a semiconductor wafer including a plurality of integrated circuits during performing of a method of dicing the semiconductor wafer, corresponding to operation 504 of the Flowchart of FIG. 5, in accordance with an embodiment of the present invention.

FIG. 6C illustrates a cross-sectional view of a semiconductor wafer including a plurality of integrated circuits during performing of a method of dicing the semiconductor wafer, corresponding to operation 506 of the Flowchart of FIG. 11, in accordance with an embodiment of the present invention.

FIG. 7 illustrates the effects of using a laser pulse in the femtosecond range versus longer pulse times, in accordance with an embodiment of the present invention.

FIG. 8 illustrates a block diagram of a tool layout for laser and plasma dicing of wafers or substrates, in accordance with an embodiment of the present invention.

FIG. 9 illustrates a block diagram of an exemplary computer system, in accordance with an embodiment of the present invention.

### DETAILED DESCRIPTION

Methods of and carriers for dicing semiconductor wafers, each wafer having a plurality of integrated circuits thereon, are described. In the following description, numerous specific details are set forth, such as substrate carriers for thin wafers, scribing and plasma etching conditions and material regimes, in order to provide a thorough understanding of embodiments of the present invention. It will be apparent to one skilled in the art that embodiments of the present invention may be practiced without these specific details. In other instances, well-known aspects, such as integrated circuit fabrication, are not described in detail in order to not unnecessarily obscure embodiments of the present invention. Furthermore, it is to be understood that the various embodiments shown in the Figures are illustrative representations and are not necessarily drawn to scale.

One or more embodiments described herein are directed to thermally resistant film frames for wafer mounting and applications of such for plasma-based wafer dicing.

To provide context, during plasma dicing of a wafer mounted on a tape frame based carrier, thermal management of the assembly including wafer/tape/frame is critical. Due to the significant differences in thermal conductivity and coefficient of thermal expansion among the wafer, the dicing or carrier tape and the film frame, the carrier tape may become distorted or damaged during plasma etching. Although not to be bound by theory, one of the damage modes may be related to the reduction of adhesion strength (or even delamination) of the dicing or carrier tape from the frame.

The above potential for damage can be especially true in the case of stainless steel film frames, which are dominant in the industry today. Stainless steel has superior thermal conductivity leading to a very uniform temperature distribution across the frame thickness. A high temperature load on the frame front side (e.g., as experienced during plasma processing) is thus readily conducted to the frame backside. However, in many cases, the dicing or carrier tape is adhered to the frame backside. Accordingly, the heating of the frame can result in weakening of the adhesion between the tape and the frame. As a consequence, the dicing or carrier tape may delaminate from the carrier frame after plasma dicing, which can be a catastrophic failure. Another potentially catastrophic failure may include a scenario where the adhesion between tape and frame is significantly weakened to an extent that the tape peels away from the frame during tape expansion for die pick.

In accordance with an embodiment of the present invention, addressing one or more of the above issues, a thermally resistant plastic frame is used for a substrate carrier. In one such embodiment, the thermally resistant plastic frame includes polyphenylene sulfide (PPS). In a specific such embodiment, a generic polyphenylene sulfide-glass fiber reinforcement material is used to fabricate a frame of a wafer carrier for use during plasma etching.

In an exemplary implementation, one or more embodiments described herein are directed to wafer dicing by (1) masking a wafer with an appropriate masking material or materials, (2) the mask being patterned at masking or subsequent to masking, the pattern being such that street areas between devices to be diced from the wafer are exposed and the areas of the wafer comprising the devices are protected by the mask, (3) the wafer being attached and supported by a carrier, (4) the carrier including a dicing tape or carrier tape supported by a thermally resistant tape frame, (5) etching the wafer by at least one of, a laser, a plasma etch, a plasma deposition, such that trenches are etched completely around the devices, and the devices being completely separated from the wafer and neighboring devices. The etching process involves etching through the wafer but stopping essentially at the interface of the carrier and wafer, or etching into the carrier but not through the carrier in such a way as to substantially reduce the structural integrity of the carrier.

In one aspect, a hybrid wafer or substrate dicing process involving an initial laser scribe and subsequent plasma etch may be implemented for die singulation. The laser scribe process may be used to cleanly remove a mask layer, organic and inorganic dielectric layers, and device layers. The laser etch process may then be terminated upon exposure of, or partial etch of, the wafer or substrate. The plasma etch portion of the dicing process may then be employed to etch through the bulk of the wafer or substrate, such as through bulk single crystalline silicon, to yield die or chip singulation or dicing. In an embodiment, the wafer or substrate is supported by a substrate carrier having a thermally resistant tape frame during the singulation process, including during the etch portion of the singulation process.

To provide context, conventional wafer dicing approaches include diamond saw cutting based on a purely mechanical separation, initial laser scribing and subsequent diamond saw dicing, or nanosecond or picosecond laser dicing. For thin wafer or substrate singulation, such as 50 microns thick bulk silicon singulation, the conventional approaches have yielded only poor process quality. Some of the challenges that may be faced when singulating die from thin wafers or substrates may include microcrack formation or delamination between different layers, chipping of inorganic dielectric layers, retention of strict kerf width control, or precise ablation depth control. Embodiments of the present invention include a hybrid laser scribing and plasma etching die singulation approach that may be useful for overcoming one or more of the above challenges.

In accordance with an embodiment of the present invention, a combination of laser scribing and plasma etching is used to dice a semiconductor wafer into individualized or singulated integrated circuits. In one embodiment, femtosecond-based laser scribing is used as an essentially, if not totally, non-thermal process. For example, the femtosecond-based laser scribing may be localized with no or negligible heat damage zone. In an embodiment, approaches herein are used to singulated integrated circuits having ultra-low k films. With convention dicing, saws may need to be slowed down to accommodate such low k films. Furthermore, semiconductor wafers are now often thinned prior to dicing. As such, in an embodiment, a combination of mask patterning and partial wafer scribing with a femtosecond-based laser, followed by a plasma etch process, is now practical. In one embodiment, direct writing with laser can eliminate need for a lithography patterning operation of a photo-resist layer and can be implemented with very little cost. In one embodiment, through-via type silicon etching is used to complete the dicing process in a plasma etching environment.

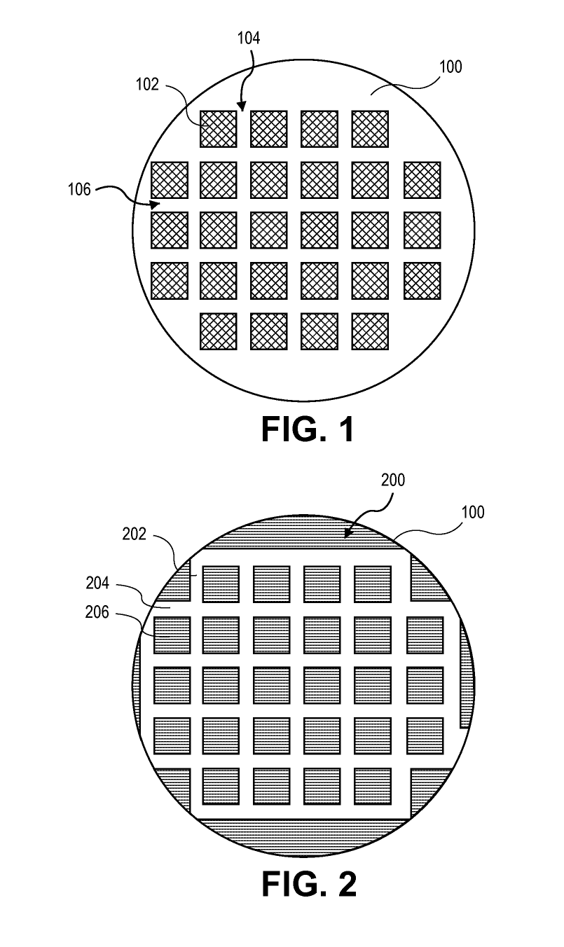

Thus, in an aspect of the present invention, a combination of laser scribing and plasma etching may be used to dice a semiconductor wafer into singulated integrated circuits. FIG. 1 illustrates a top plan of a semiconductor wafer to be diced, in accordance with an embodiment of the present invention. FIG. 2 illustrates a top plan of a semiconductor wafer to be diced that has a dicing mask formed thereon, in accordance with an embodiment of the present invention.

Referring to FIG. 1, a semiconductor wafer 100 has a plurality of regions 102 that include integrated circuits. The regions 102 are separated by vertical streets 104 and horizontal streets 106. The streets 104 and 106 are areas of semiconductor wafer that do not contain integrated circuits and are designed as locations along which the wafer will be diced. Some embodiments of the present invention involve the use of a combination laser scribe and plasma etch technique to cut trenches through the semiconductor wafer along the streets such that the dice are separated into individual chips or die. Since both a laser scribe and a plasma etch process are crystal structure orientation independent, the crystal structure of the semiconductor wafer to be diced may be immaterial to achieving a vertical trench through the wafer.

Referring to FIG. 2, the semiconductor wafer 100 has a mask 200 deposited upon the semiconductor wafer 100. In one embodiment, the mask is deposited in a conventional manner to achieve an approximately 4-10 micron thick layer. The mask 200 and a portion of the semiconductor wafer 100 are, in one embodiment, patterned with a laser scribing process to define the locations (e.g., gaps 202 and 204) along the streets 104 and 106 where the semiconductor wafer 100 will be diced. The integrated circuit regions of the semiconductor wafer 100 are covered and protected by the mask 200. The regions 206 of the mask 200 are positioned such that during a subsequent etching process, the integrated circuits are not degraded by the etch process. Horizontal gaps 204 and vertical gaps 202 are formed between the regions 206 to define the areas that will be etched during the etching process to finally dice the semiconductor wafer 100. In accordance with an embodiment of the present invention, the semiconductor wafer 100 is supported by a wafer carrier during one or both of the laser scribing and/or plasma etching processes. In one such embodiment, the wafer carrier includes a thermally resistant tape frame.

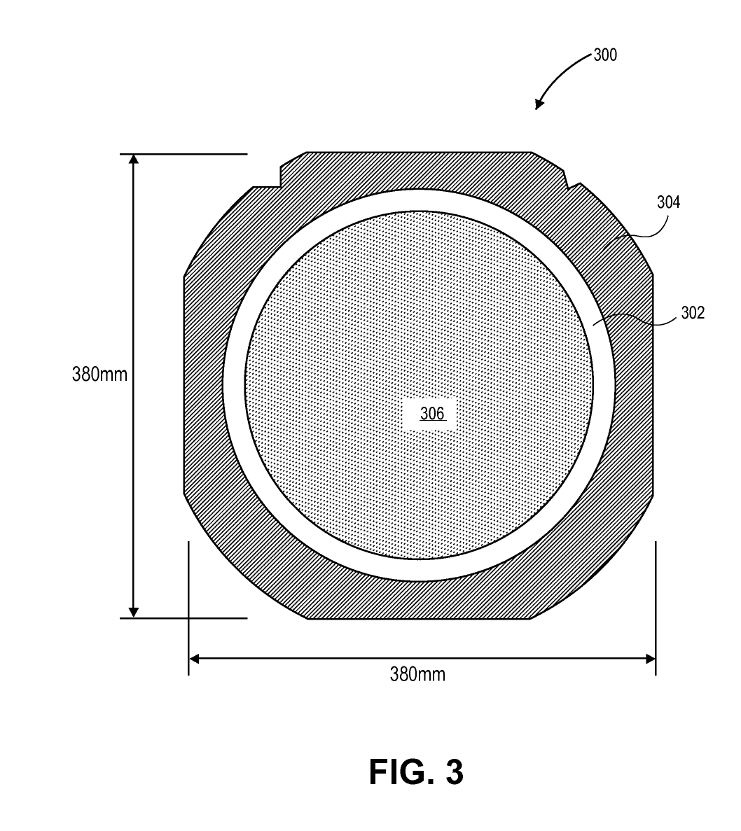

As mentioned briefly above, in an embodiment, a substrate for dicing is supported by a substrate carrier during the plasma etching portion of a die singulation process, e.g., of a hybrid laser ablation and plasma etching singulation scheme. For example, FIG. 3 illustrates a plan view of a substrate carrier suitable for supporting a wafer during a singulation process, in accordance with an embodiment of the present invention.

Referring to FIG. 3, a substrate carrier 300 includes a layer of backing tape 302 surrounded by a tape ring or frame 304. A wafer or substrate 306 is supported by the backing tape 302 of the substrate carrier 300. In one embodiment, the wafer or substrate 306 is attached to the backing tape 302 by a die attach film. In one embodiment, the tape ring 304 is composed of a thermally resistant material.

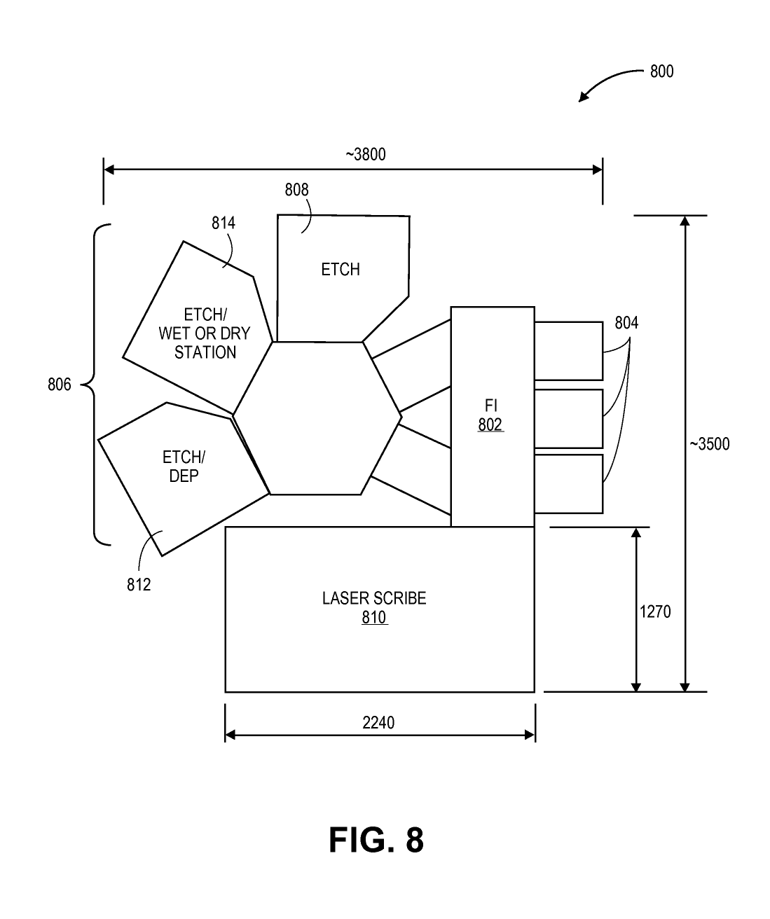

In an embodiment, a singulation process can be accommodated in a system sized to receive a substrate carrier such as the substrate carrier 300. In one such embodiment, a system such as system 800, described in greater detail below in association with FIG. 8, can accommodate a wafer frame without impact on the system footprint that is otherwise sized to accommodate a substrate or wafer not supported by a substrate carrier. In one embodiment, such a processing system is sized to accommodate 300 millimeter-in-diameter wafers or substrates. The same system can accommodate a wafer carrier approximately 380 millimeters in width by 380 millimeters in length, as depicted in FIG. 3. However, it is to be appreciated that systems may be designed to handle 450 millimeter wafers or substrate or, more particularly, 450 millimeter wafer or substrate carriers.

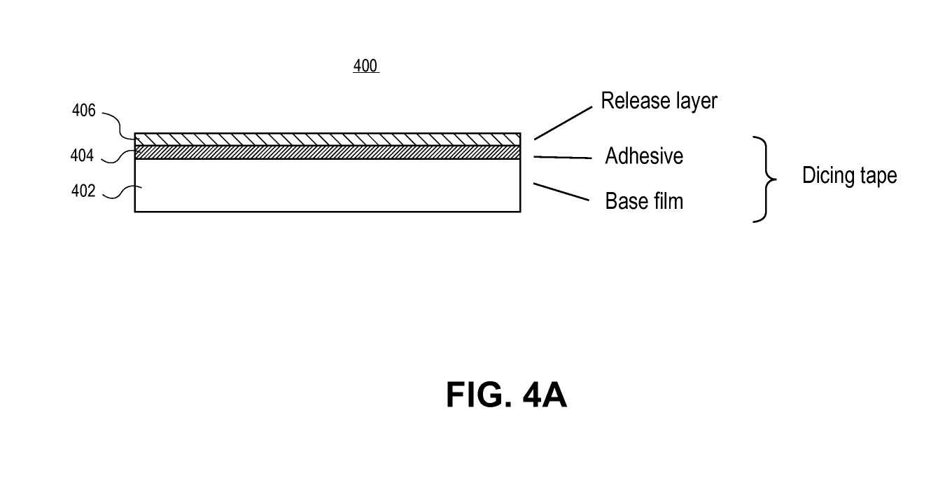

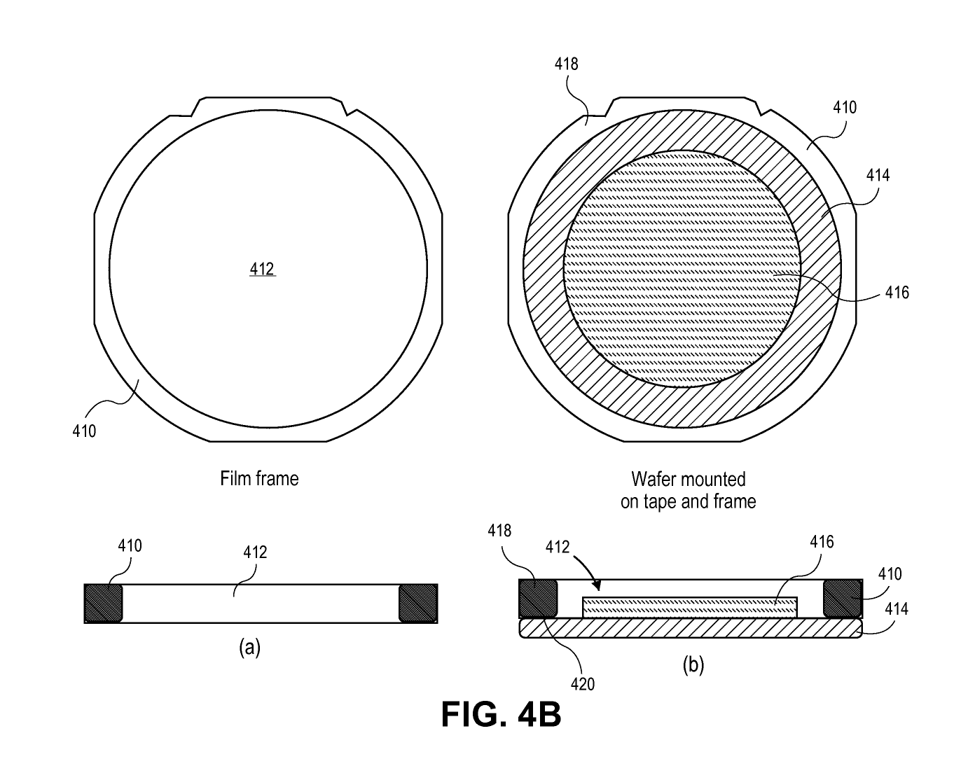

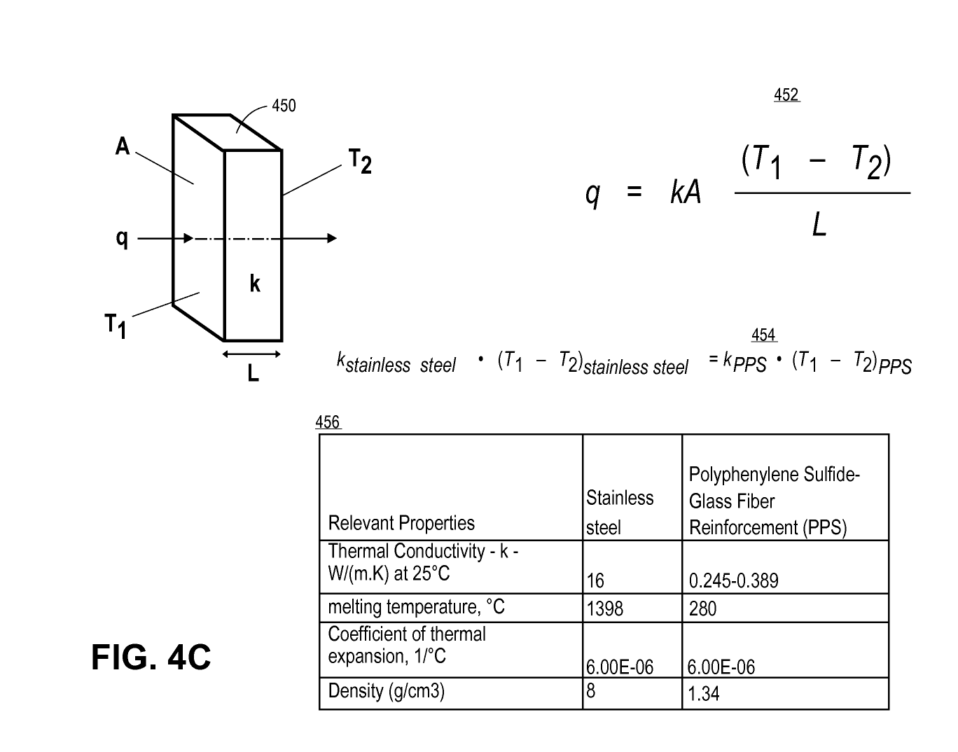

A wafer or substrate carrier may include a tape included either within, or supported from above by, a carrier film frame. As an example of a suitable tape, FIG. 4A illustrates a cross-sectional view of a carrier tape, in accordance with an embodiment of the present invention. Referring to FIG. 4A, a tape 400 includes a base film 402. An adhesive layer 404 is disposed on the base film 402.

Together, the base film 402 and the adhesive film 404 may be referred to as a dicing tape or a carrier tape or a backing tape. In an embodiment, the adhesive layer is a thermally curable or an ultra-violet (UV)-curable adhesive layer. In one such embodiment, the adhesive strength of the adhesive layer 404 weakens upon such curing in order to enable die pick from the adhesive layer 404 following a singulation process. In an embodiment, the adhesive layer 404 or the base film 402, or both, is thermally sensitive. In an embodiment, the base film 402 is a flexible, stretchable membrane.

Referring again to FIG. 4A, a release layer 406 may be included as disposed on the adhesive layer 404. In one such embodiment, the release layer 406 is removed prior to adhering a wafer or substrate to the adhesive layer 404 for processing.

FIG. 4B illustrates a plan view and corresponding cross-sectional view of (a) a film frame (also referred to as a tape frame), and (b) a wafer and carrier assembly, in accordance with an embodiment of the present invention. Referring to part (a) of FIG. 4B, a film frame 410 has an inner opening 412. Referring to part (b) of FIG. 4B, the film frame 410 is coupled to a dicing or carrier tape 414. In one embodiment, the film frame 410 is mounted on the dicing or carrier tape 414, as is depicted in FIG. 4B. However, in other embodiment, the dicing or carrier tape 414 is included only within the inner opening 412, and is affixed to the inner surface of the frame 410. In either case, the dicing or carrier tape 414 can be used to support a wafer or substrate 416 within the inner opening 412 of the film frame 410, as is depicted in FIG. 4B.

A heat load on the front surface 418 of the film frame 410 (e.g., as may be experienced during plasma processing) may be conducted to the frame backside 420 and can adversely affect dicing or carrier tape 414 adhesion to the film frame 410. However, in accordance with an embodiment of the present invention, the film frame 410 is composed of a thermally resistant material. In one such embodiment, the thermally resistant material can effectively mitigate or eliminate conduction of a heat load from the front surface 418 of the film frame 410 to the frame backside 420.

In an embodiment, the film frame 410 includes a polyphenylene sulfide (PPS) material. In a specific such embodiment, the polyphenylene sulfide is reinforced by glass fiber to provide a material suitable for fabricating a frame of a wafer carrier.

In an embodiment, the dicing or carrier tape 414 includes a base film, such as the base film 402 described in association with FIG. 4A. In one such embodiment, the dicing or carrier tape 414 further includes an adhesive layer disposed on the base film, such as adhesive layer 404 described in association with FIG. 4A. In a specific embodiment, the adhesive layer is a thermally curable or an ultra-violet (UV)-curable adhesive layer. In another specific embodiment, one or both of the adhesive layer and the base film is thermally sensitive. In that case, a heat load that would otherwise be transferred through a stainless-steel film frame would be sufficient to damage the adhesive layer or the base film, or both. However, in one embodiment, use of a thermally resistant film frame mitigates or eliminates such damage by inhibiting conduction of the heat load by the frame itself.

In an embodiment, prior to adhering the wafer or substrate 416 to the dicing or carrier tape 414, a release layer is disposed on an adhesive layer of the dicing or carrier tape 414. The release layer is removed in preparation for adhering the wafer or substrate 416 to the dicing or carrier tape 414. In one such embodiment, following removal of the release layer, a die-attach-film (DAF) is used as an intermediate layer to the dicing or carrier tape 414 and the wafer or substrate 416. Such a die-attach-film can be disposed on the dicing or carrier tape 414 independently or can be delivered as already affixed to the backside of the wafer or substrate 416. Thus, arrangements can include a die-attach film disposed directly between a base film and a substrate or wafer (if no adhesive layer is used), or disposed directly between a substrate or wafer and an adhesive layer of the dicing tape. In one embodiment, if present, a die-attach-film may become a part of a singulated die.

FIG. 4C includes equations and material properties for determining a suitable thermally resistant material for a film frame of a substrate carrier, in accordance with an embodiment of the present invention. Referring to FIG. 4C, thermal conduction of a material 450 can be determined using equation 452. Using equation 452, heat input, q, is a function of thermal conductivity, k, frame surface area, A, frame thickness, L, and the difference of frame front side temperature (T1) and frame backside temperature (T2).

Using the above information, a comparison between two materials be determined, e.g., between stainless steel and polyphenylene sulfide (PPS). More specifically, for a given q, A, L, and T1, equation 454 may be used to compare backside temperatures of the competing frame materials. Using the parameters from table 456, for a thermal insulating plastic frame such as PPS, the temperature on the frame backside surface (T2), which adheres to a dicing tape, is much lower than that of stainless steel frame (T2). In an example, if T1 is assumed to be 180° C. for both frames, and let T_{2,pps}=30° C., then T_{2,stainless steel}=approximately 176-178° C., which is approximately equal to T1. The chance for tape delamination or thermal damage in the case of stainless steel is much greater than in the case for PPS material. As such, in an embodiment, use of a PPS-based film frame can significantly reduce the temperature at the frame backside/dicing tape interface due to its much higher thermal resistance as compared to stainless steel. Hence, the likelihood of weakening adhesion between a PPS frame backside and the dicing tape (or causing dicing tape delamination) is much lower than using stainless steel frame. Furthermore, in an embodiment, the rigidity and dimensional stability of a PPS frame is essentially the same as that of a stainless-steel frame.

In an embodiment, a substrate carrier such as described in the embodiments associated with FIGS. 4A-4C is used to support a wafer or substrate in a plasma processing operation, such as a plasma etching operation. In one such embodiment, an etch process is specifically performed to completely etch through the wafer to singulate integrated circuits while not etching through the carrier in any way that might compromise the structural integrity of the carrier through the etch process and possibly, through a subsequent die pick operation which may involve stretching or expansion of the supporting tape. In one such embodiment, the supporting tape is removed from the frame prior to expansion of the tape.

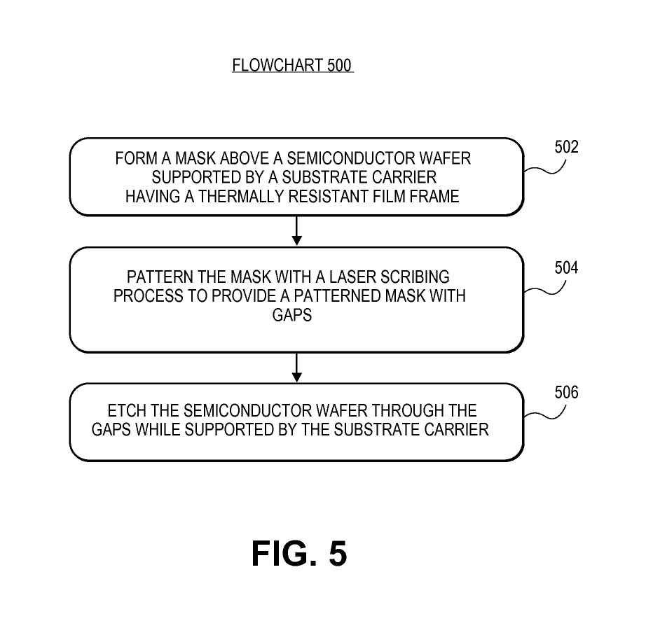

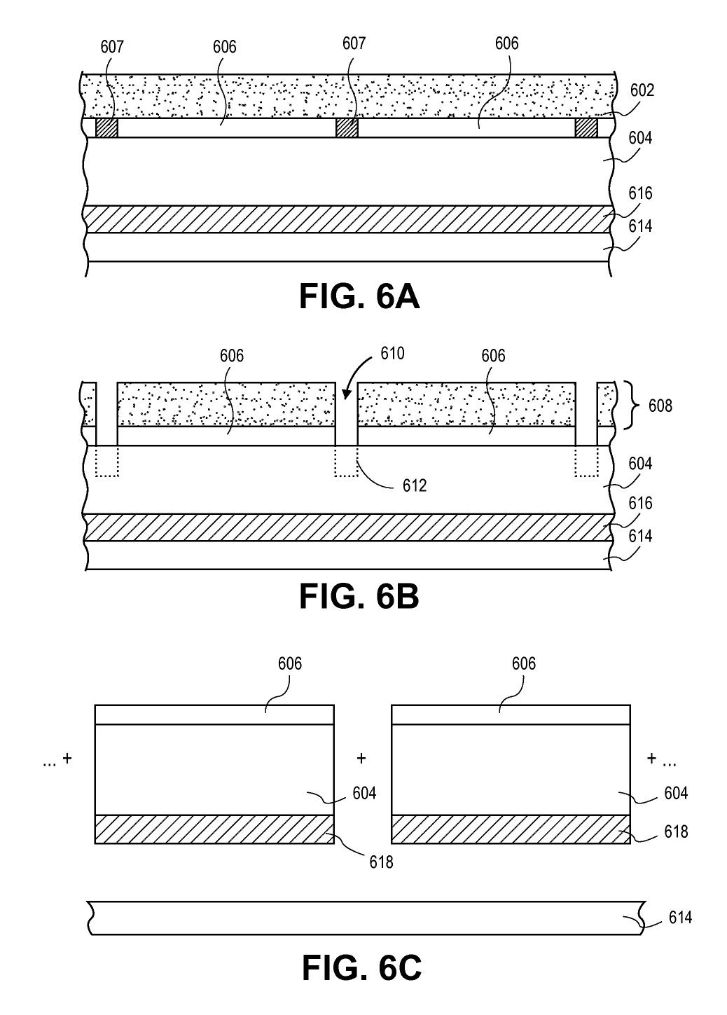

In another aspect, FIG. 5 is a Flowchart 500 representing operations in a method of dicing a semiconductor wafer including a plurality of integrated circuits, in accordance with an embodiment of the present invention. FIGS. 6A-6C illustrate cross-sectional views of a semiconductor wafer including a plurality of integrated circuits during performing of a method of dicing the semiconductor wafer, corresponding to operations of Flowchart 500, in accordance with an embodiment of the present invention.

Referring to operation 502 of Flowchart 500, and corresponding FIG. 6A, a mask 602 is formed above a semiconductor wafer or substrate 604. The mask 602 is composed of a layer covering and protecting integrated circuits 606 formed on the surface of semiconductor wafer 604. The mask 602 also covers intervening streets 607 formed between each of the integrated circuits 606. The semiconductor wafer or substrate 604 is supported by a substrate carrier 614 such as described in association with FIGS. 3 and 4A-4C, e.g., a substrate carrier having a thermally resistant film frame.

In an embodiment, the substrate carrier 614 includes a layer of backing tape, a portion of which is depicted as 614 in FIG. 6A, surrounded by a thermally resistant tape ring or frame (not shown). In one such embodiment, the semiconductor wafer or substrate 604 is disposed on a die attach film 616 disposed on the substrate carrier 614, as is depicted in FIG. 6A.

In accordance with an embodiment of the present invention, forming the mask 602 includes forming a layer such as, but not limited to, a photo-resist layer or an I-line patterning layer. For example, a polymer layer such as a photo-resist layer may be composed of a material otherwise suitable for use in a lithographic process. In one embodiment, the photo-resist layer is composed of a positive photo-resist material such as, but not limited to, a 248 nanometer (nm) resist, a 193 nm resist, a 157 nm resist, an extreme ultra-violet (EUV) resist, or a phenolic resin matrix with a diazonaphthoquinone sensitizer. In another embodiment, the photo-resist layer is composed of a negative photo-resist material such as, but not limited to, poly-cis-isoprene and poly-vinyl-cinnamate.

In another embodiment, the mask 602 is a water-soluble mask layer. In an embodiment, the water-soluble mask layer is readily dissolvable in an aqueous media. For example, in one embodiment, the water-soluble mask layer is composed of a material that is soluble in one or more of an alkaline solution, an acidic solution, or in deionized water. In an embodiment, the water-soluble mask layer maintains its water solubility upon exposure to a heating process, such as heating approximately in the range of 50-160 degrees Celsius. For example, in one embodiment, the water-soluble mask layer is soluble in aqueous solutions following exposure to chamber conditions used in a laser and plasma etch singulation process. In one embodiment, the water-soluble mask layer is composed of a material such as, but not limited to, polyvinyl alcohol, polyacrylic acid, dextran, polymethacrylic acid, polyethylene imine, or polyethylene oxide. In a specific embodiment, the water-soluble mask layer has an etch rate in an aqueous solution approximately in the range of 1-15 microns per minute and, more particularly, approximately 1.3 microns per minute.

In another embodiment, the mask 602 is a UV-curable mask layer. In an embodiment, the mask layer has a susceptibility to UV light that reduces an adhesiveness of the UV-curable layer by at least approximately 80%. In one such embodiment, the UV layer is composed of polyvinyl chloride or an acrylic-based material. In an embodiment, the UV-curable layer is composed of a material or stack of materials with an adhesive property that weakens upon exposure to UV light. In an embodiment, the UV-curable adhesive film is sensitive to approximately 365 nm UV light. In one such embodiment, this sensitivity enables use of LED light to perform a cure.

In an embodiment, the semiconductor wafer or substrate 604 is composed of a material suitable to withstand a fabrication process and upon which semiconductor processing layers may suitably be disposed. For example, in one embodiment, semiconductor wafer or substrate 604 is composed of a group IV-based material such as, but not limited to, crystalline silicon, germanium or silicon/germanium. In a specific embodiment, providing semiconductor wafer 604 includes providing a monocrystalline silicon substrate. In a particular embodiment, the monocrystalline silicon substrate is doped with impurity atoms. In another embodiment, semiconductor wafer or substrate 604 is composed of a III-V material such as, e.g., a III-V material substrate used in the fabrication of light emitting diodes (LEDs).

In an embodiment, the semiconductor wafer or substrate 604 has a thickness of approximately 300 microns or less. For example, in one embodiment, a bulk single-crystalline silicon substrate is thinned from the backside prior to being affixed to the die attach film 616. The thinning may be performed by a backside grind process. In one embodiment, the bulk single-crystalline silicon substrate is thinned to a thickness approximately in the range of 50-300 microns. It is important to note that, in an embodiment, the thinning is performed prior to a laser ablation and plasma etch dicing process. In an embodiment, the die attach film 616 (or any suitable substitute capable of bonding a thinned or thin wafer or substrate to the substrate carrier 614) has a thickness of approximately 20 microns.

In an embodiment, the semiconductor wafer or substrate 604 has disposed thereon or therein, as a portion of the integrated circuits 606, an array of semiconductor devices. Examples of such semiconductor devices include, but are not limited to, memory devices or complimentary metal-oxide-semiconductor (CMOS) transistors fabricated in a silicon substrate and encased in a dielectric layer. A plurality of metal interconnects may be formed above the devices or transistors, and in surrounding dielectric layers, and may be used to electrically couple the devices or transistors to form the integrated circuits 606. Materials making up the streets 607 may be similar to or the same as those materials used to form the integrated circuits 606. For example, streets 607 may be composed of layers of dielectric materials, semiconductor materials, and metallization. In one embodiment, one or more of the streets 607 includes test devices similar to the actual devices of the integrated circuits 606.

Referring to operation 604 of Flowchart 600, and corresponding FIG. 6B, the mask 602 is patterned with a laser scribing process to provide a patterned mask 608 with gaps 610, exposing regions of the semiconductor wafer or substrate 604 between the integrated circuits 606. In one such embodiment, the laser scribing process is a femtosecond-based laser scribing process. The laser scribing process is used to remove the material of the streets 607 originally formed between the integrated circuits 606. In accordance with an embodiment of the present invention, patterning the mask 602 with the laser scribing process includes forming trenches 612 partially into the regions of the semiconductor wafer 604 between the integrated circuits 606, as is depicted in FIG. 6B.

In other embodiments, however, instead of a laser scribing process, patterning of the mask may be achieved by, e.g., screen printing a patterned mask, photo-lithography, or by applying a pre-patterned dry laminate mask. In other embodiments, maskless processes are used, such as an approach employing a dry laminate underfill layer as a mask.

In an embodiment, patterning the mask 602 with the laser scribing process includes using a laser having a pulse width in the femtosecond range. Specifically, a laser with a wavelength in the visible spectrum plus the ultra-violet (UV) and infra-red (IR) ranges (totaling a broadband optical spectrum) may be used to provide a femtosecond-based laser, i.e., a laser with a pulse width on the order of the femtosecond (10⁻¹⁵ seconds). In one embodiment, ablation is not, or is essentially not, wavelength dependent and is thus suitable for complex films such as films of the mask 602, the streets 607 and, possibly, a portion of the semiconductor wafer or substrate 604.

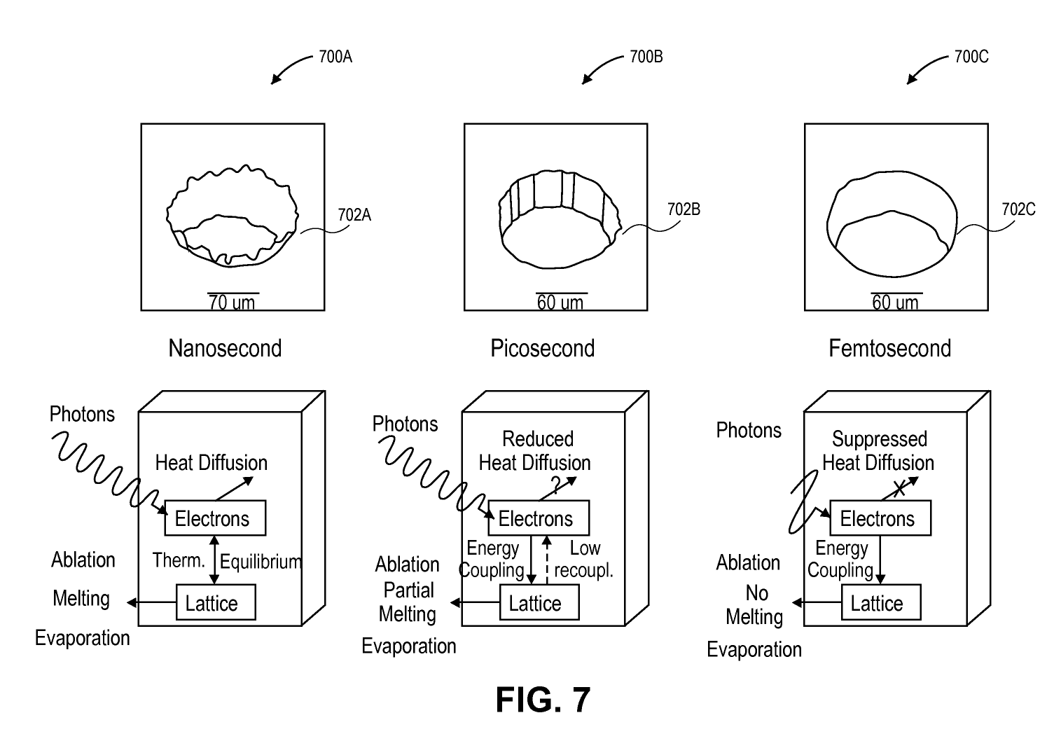

FIG. 7 illustrates the effects of using a laser pulse in the femtosecond range versus longer frequencies, in accordance with an embodiment of the present invention. Referring to FIG. 7, by using a laser with a pulse width in the femtosecond range heat damage issues are mitigated or eliminated (e.g., minimal to no damage 702C with femtosecond processing of a via 700C) versus longer pulse widths (e.g., damage 702B with picosecond processing of a via 700B and significant damage 702A with nanosecond processing of a via 700A). The elimination or mitigation of damage during formation of via 700C may be due to a lack of low energy recoupling (as is seen for picosecond-based laser ablation) or thermal equilibrium (as is seen for nanosecond-based laser ablation), as depicted in FIG. 7.

Laser parameters selection, such as pulse width, may be critical to developing a successful laser scribing and dicing process that minimizes chipping, microcracks and delamination in order to achieve clean laser scribe cuts. The cleaner the laser scribe cut, the smoother an etch process that may be performed for ultimate die singulation. In semiconductor device wafers, many functional layers of different material types (e.g., conductors, insulators, semiconductors) and thicknesses are typically disposed thereon. Such materials may include, but are not limited to, organic materials such as polymers, metals, or inorganic dielectrics such as silicon dioxide and silicon nitride.

By contrast, if non-optimal laser parameters are selected, in a stacked structure that involves, e.g., two or more of an inorganic dielectric, an organic dielectric, a semiconductor, or a metal, a laser ablation process may cause delamination issues. For example, a laser penetrate through high bandgap energy dielectrics (such as silicon dioxide with an approximately of 9 eV bandgap) without measurable absorption. However, the laser energy may be absorbed in an underlying metal or silicon layer, causing significant vaporization of the metal or silicon layers. The vaporization may generate high pressures to lift-off the overlying silicon dioxide dielectric layer and potentially causing severe interlayer delamination and microcracking. In an embodiment, while picoseconds-based laser irradiation processes lead to microcracking and delaminating in complex stacks, femtosecond-based laser irradiation processes have been demonstrated to not lead to microcracking or delamination of the same material stacks.

In order to be able to directly ablate dielectric layers, ionization of the dielectric materials may need to occur such that they behave similar to a conductive material by strongly absorbing photons. The absorption may block a majority of the laser energy from penetrating through to underlying silicon or metal layers before ultimate ablation of the dielectric layer. In an embodiment, ionization of inorganic dielectrics is feasible when the laser intensity is sufficiently high to initiate photon-ionization and impact ionization in the inorganic dielectric materials.

In accordance with an embodiment of the present invention, suitable femtosecond-based laser processes are characterized by a high peak intensity (irradiance) that usually leads to nonlinear interactions in various materials. In one such embodiment, the femtosecond laser sources have a pulse width approximately in the range of 10 femtoseconds to 500 femtoseconds, although preferably in the range of 100 femtoseconds to 400 femtoseconds. In one embodiment, the femtosecond laser sources have a wavelength approximately in the range of 1570 nanometers to 200 nanometers, although preferably in the range of 540 nanometers to 250 nanometers. In one embodiment, the laser and corresponding optical system provide a focal spot at the work surface approximately in the range of 3 microns to 15 microns, though preferably approximately in the range of 5 microns to 10 microns.

The spacial beam profile at the work surface may be a single mode (Gaussian) or have a shaped top-hat profile. In an embodiment, the laser source has a pulse repetition rate approximately in the range of 200 kHz to 10 MHz, although preferably approximately in the range of 500 kHz to 5 MHz. In an embodiment, the laser source delivers pulse energy at the work surface approximately in the range of 0.5 uJ to 100 uJ, although preferably approximately in the range of 1 uJ to 5uJ. In an embodiment, the laser scribing process runs along a work piece surface at a speed approximately in the range of 500 mm/sec to 5 m/sec, although preferably approximately in the range of 600 mm/sec to 2 m/sec.

The scribing process may be run in single pass only, or in multiple passes, but, in an embodiment, preferably 1-2 passes. In one embodiment, the scribing depth in the work piece is approximately in the range of 5 microns to 50 microns deep, preferably approximately in the range of 10 microns to 20 microns deep. The laser may be applied either in a train of single pulses at a given pulse repetition rate or a train of pulse bursts. In an embodiment, the kerf width of the laser beam generated is approximately in the range of 2 microns to 15 microns, although in silicon wafer scribing/dicing preferably approximately in the range of 6 microns to 10 microns, measured at the device/silicon interface.

Laser parameters may be selected with benefits and advantages such as providing sufficiently high laser intensity to achieve ionization of inorganic dielectrics (e.g., silicon dioxide) and to minimize delamination and chipping caused by underlayer damage prior to direct ablation of inorganic dielectrics. Also, parameters may be selected to provide meaningful process throughput for industrial applications with precisely controlled ablation width (e.g., kerf width) and depth. As described above, a femtosecond-based laser is far more suitable to providing such advantages, as compared with picosecond-based and nanosecond-based laser ablation processes. However, even in the spectrum of femtosecond-based laser ablation, certain wavelengths may provide better performance than others. For example, in one embodiment, a femtosecond-based laser process having a wavelength closer to or in the UV range provides a cleaner ablation process than a femtosecond-based laser process having a wavelength closer to or in the IR range. In a specific such embodiment, a femtosecond-based laser process suitable for semiconductor wafer or substrate scribing is based on a laser having a wavelength of approximately less than or equal to 540 nanometers. In a particular such embodiment, pulses of approximately less than or equal to 400 femtoseconds of the laser having the wavelength of approximately less than or equal to 540 nanometers are used. However, in an alternative embodiment, dual laser wavelengths (e.g., a combination of an IR laser and a UV laser) are used.

Referring to operation 506 of Flowchart 500, and corresponding FIG. 6C, the semiconductor wafer or substrate 604 is etched through the gaps 610 in the patterned mask 608 to singulate the integrated circuits 606. In accordance with an embodiment of the present invention, etching the semiconductor wafer 604 includes etching to extend the trenches 612 formed with the laser scribing process and to ultimately etch entirely through semiconductor wafer or substrate 604, as depicted in FIG. 6C.

In an embodiment, etching the semiconductor wafer or substrate 604 includes using a plasma etching process. In one embodiment, a through-silicon via type etch process is used. For example, in a specific embodiment, the etch rate of the material of semiconductor wafer or substrate 604 is greater than 25 microns per minute. An ultra-high-density plasma source may be used for the plasma etching portion of the die singulation process. An example of a process chamber suitable to perform such a plasma etch process is the Applied Centura® Silvia™ Etch system available from Applied Materials of Sunnyvale, Calif., USA. The Applied Centura® Silvia™ Etch system combines the capacitive and inductive RF coupling, which gives much more independent control of the ion density and ion energy than was possible with the capacitive coupling only, even with the improvements provided by magnetic enhancement. The combination enables effective decoupling of the ion density from ion energy, so as to achieve relatively high density plasmas without the high, potentially damaging, DC bias levels, even at very low pressures. An exceptionally wide process window results. However, any plasma etch chamber capable of etching silicon may be used. In an exemplary embodiment, a deep silicon etch is used to etch a single crystalline silicon substrate or wafer 604 at an etch rate greater than approximately 40% of conventional silicon etch rates while maintaining essentially precise profile control and virtually scallop-free sidewalls. In a specific embodiment, a through-silicon via type etch process is used. The etch process is based on a plasma generated from a reactive gas, which generally a fluorine-based gas such as SF₆, C₄ F₈, CHF₃, XeF₂, or any other reactant gas capable of etching silicon at a relatively fast etch rate. In one embodiment, however, a Bosch process is used which involves formation of a scalloped profile.

Referring again to FIG. 6C, in accordance with an embodiment of the present invention, a substrate or wafer carrier having a thermally resistant film frame is accommodated in an etch chamber during a singulation process. In an embodiment, the assembly including a wafer or substrate on the substrate carrier is subjected to a plasma etch reactor without affecting (e.g., etching) the film frame (e.g., tape ring 304) and the film (e.g., backing tape 302).

In an embodiment, singulation may further include patterning of die attach film 616. In one embodiment, die attach film 616 is patterned by a technique such as, but not limited to, laser ablation, dry (plasma) etching or wet etching. In an embodiment, the die attach film 616 is patterned in sequence following the laser scribe and plasma etch portions of the singulation process to provide die attach film portions 618, as depicted in FIG. 6C. In an embodiment, the patterned mask 608 is removed after the laser scribe and plasma etch portions of the singulation process, as is also depicted in FIG. 6C. The patterned mask 608 may be removed prior to, during, or following patterning of the die attach film 616. In an embodiment, the semiconductor wafer or substrate 604 is etched while supported by the substrate carrier 614. In an embodiment, the die attach film 616 is also patterned while disposed on the substrate carrier 614.

Accordingly, referring again to Flowchart 500 and FIGS. 6A-6C, wafer dicing may be preformed by initial laser ablation through a mask, through wafer streets (including metallization), and partially into a silicon substrate. The laser pulse width may be selected in the femtosecond range. Die singulation may then be completed by subsequent through-silicon deep plasma etching. Additionally, removal of exposed portions of the die attach film is performed to provide singulated integrated circuits, each having a portion of a die attach film thereon. The individual integrated circuits, including die attach film portions may then be removed from the substrate carrier 614, as depicted in FIG. 6C. In an embodiment, the singulated integrated circuits are removed from the substrate carrier 614 for packaging. In one such embodiment, the patterned die attach film 618 is retained on the backside of each integrated circuit and included in the final packaging. However, in another embodiment, the patterned die attach film 614 is removed during or subsequent to the singulation process.

A single process tool may be configured to perform many or all of the operations in a hybrid laser ablation and plasma etch singulation process. For example, FIG. 8 illustrates a block diagram of a tool layout for laser and plasma dicing of wafers or substrates, in accordance with an embodiment of the present invention.

Referring to FIG. 8, a process tool 800 includes a factory interface 802 (FI) having a plurality of load locks 804 coupled therewith. A cluster tool 806 is coupled with the factory interface 802. The cluster tool 806 includes one or more plasma etch chambers, such as plasma etch chamber 808. A laser scribe apparatus 810 is also coupled to the factory interface 802. The overall footprint of the process tool 800 may be, in one embodiment, approximately 3500 millimeters (3.5 meters) by approximately 3800 millimeters (3.8 meters), as depicted in FIG. 8.

In an embodiment, the laser scribe apparatus 810 houses a femtosecond-based laser. The femtosecond-based laser may be suitable for performing a laser ablation portion of a hybrid laser and etch singulation process, such as the laser abalation processes described above. In one embodiment, a moveable stage is also included in laser scribe apparatus 800, the moveable stage configured for moving a wafer or substrate (or a carrier thereof) relative to the femtosecond-based laser. In a specific embodiment, the femtosecond-based laser is also moveable. The overall footprint of the laser scribe apparatus 810 may be, in one embodiment, approximately 2240 millimeters by approximately 1270 millimeters, as depicted in FIG. 8.

In an embodiment, the one or more plasma etch chambers 808 is configured for etching a wafer or substrate through the gaps in a patterned mask to singulate a plurality of integrated circuits. In one such embodiment, the one or more plasma etch chambers 808 is configured to perform a deep silicon etch process. In a specific embodiment, the one or more plasma etch chambers 808 is an Applied Centura® Silvia™ Etch system, available from Applied Materials of Sunnyvale, Calif., USA. The etch chamber may be specifically designed for a deep silicon etch used to create singulate integrated circuits housed on or in single crystalline silicon substrates or wafers. In an embodiment, a high-density plasma source is included in the plasma etch chamber 808 to facilitate high silicon etch rates. In an embodiment, more than one etch chamber is included in the cluster tool 806 portion of process tool 800 to enable high manufacturing throughput of the singulation or dicing process.

The factory interface 802 may be a suitable atmospheric port to interface between an outside manufacturing facility with laser scribe apparatus 810 and cluster tool 806. The factory interface 802 may include robots with arms or blades for transferring wafers (or carriers thereof) from storage units (such as front opening unified pods) into either cluster tool 806 or laser scribe apparatus 810, or both.

Cluster tool 806 may include other chambers suitable for performing functions in a method of singulation. For example, in one embodiment, in place of an additional etch chamber, a deposition chamber 812 is included. The deposition chamber 812 may be configured for mask deposition on or above a device layer of a wafer or substrate prior to laser scribing of the wafer or substrate. In one such embodiment, the deposition chamber 812 is suitable for depositing a water soluble mask layer. In another embodiment, in place of an additional etch chamber, a wet/dry station 814 is included. The wet/dry station may be suitable for cleaning residues and fragments, or for removing a water soluble mask, subsequent to a laser scribe and plasma etch singulation process of a substrate or wafer. In an embodiment, a metrology station is also included as a component of process tool 800.

Embodiments of the present invention may be provided as a computer program product, or software, that may include a machine-readable medium having stored thereon instructions, which may be used to program a computer system (or other electronic devices) to perform a process according to embodiments of the present invention. In one embodiment, the computer system is coupled with process tool 800 described in association with FIG. 8. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

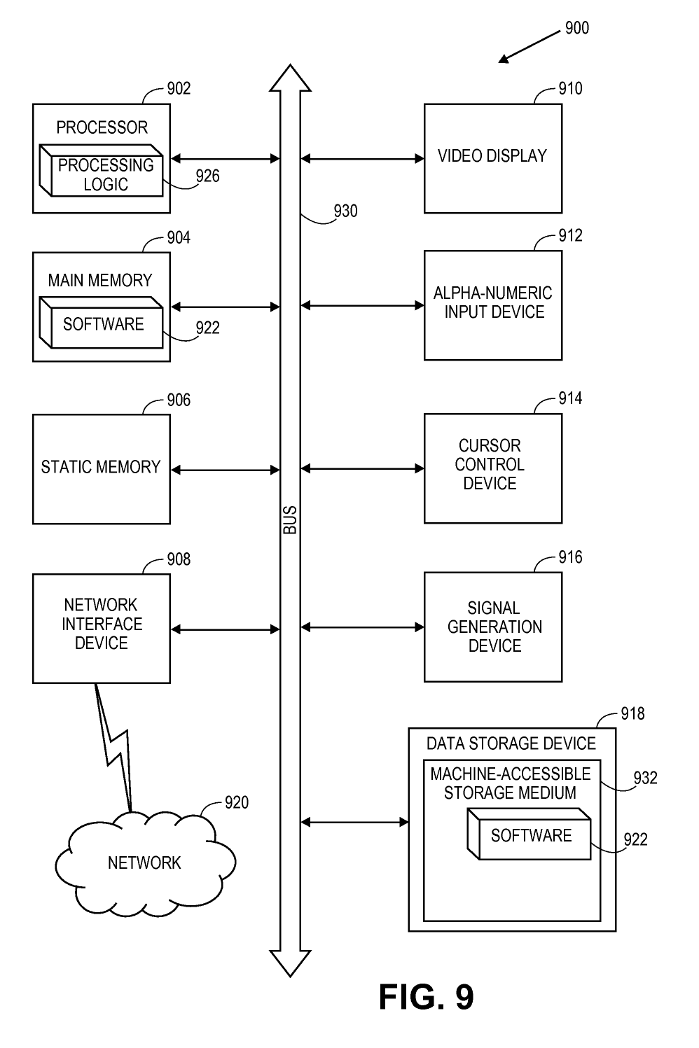

FIG. 9 illustrates a diagrammatic representation of a machine in the exemplary form of a computer system 900 within which a set of instructions, for causing the machine to perform any one or more of the methodologies described herein (such as end-point detection), may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 900 includes a processor 902, a main memory 904 (e.g., read-only memory (ROM), flash memory, dynamic random access memory (DRAM) such as synchronous DRAM (SDRAM) or Rambus DRAM (RDRAM), etc.), a static memory 906 (e.g., flash memory, static random access memory (SRAM), etc.), and a secondary memory 918 (e.g., a data storage device), which communicate with each other via a bus 930.

Processor 902 represents one or more general-purpose processing devices such as a microprocessor, central processing unit, or the like. More particularly, the processor 902 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 902 may also be one or more special-purpose processing devices such as an application specific integrated circuit (ASIC), a field programmable gate array (FPGA), a digital signal processor (DSP), network processor, or the like. Processor 902 is configured to execute the processing logic 926 for performing the operations described herein.

The computer system 900 may further include a network interface device 908. The computer system 900 also may include a video display unit 910 (e.g., a liquid crystal display (LCD), a light emitting diode display (LED), or a cathode ray tube (CRT)), an alphanumeric input device 912 (e.g., a keyboard), a cursor control device 914 (e.g., a mouse), and a signal generation device 916 (e.g., a speaker).

The secondary memory 918 may include a machine-accessible storage medium (or more specifically a computer-readable storage medium) 932 on which is stored one or more sets of instructions (e.g., software 922) embodying any one or more of the methodologies or functions described herein. The software 922 may also reside, completely or at least partially, within the main memory 904 and/or within the processor 902 during execution thereof by the computer system 900, the main memory 904 and the processor 902 also constituting machine-readable storage media. The software 922 may further be transmitted or received over a network 920 via the network interface device 908.

While the machine-accessible storage medium 932 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present invention. The term “machine-readable storage medium” shall accordingly be taken to include, but not be limited to, solid-state memories, and optical and magnetic media.

In accordance with an embodiment of the present invention, a machine-accessible storage medium has instructions stored thereon which cause a data processing system to perform a method of dicing a semiconductor wafer having a plurality of integrated circuits.

Thus, methods of and carriers for dicing semiconductor wafers, each wafer having a plurality of integrated circuits, have been disclosed.

What is claimed is:

1. A method of dicing a semiconductor wafer comprising a front surface having a plurality of integrated circuits thereon, the method comprising:
providing the semiconductor wafer having a patterned mask covering the integrated circuits and having scribe lines between the integrated circuits; and
plasma etching the semiconductor wafer through the scribe lines to singulate the integrated circuits, wherein the semiconductor wafer is supported on a tape of a substrate carrier having a thermally resistant frame during the plasma etching.

2. The method of claim 1, further comprising:
subsequent to plasma etching the semiconductor wafer, expanding the tape of the substrate carrier and performing a die pick operation.

3. The method of claim 1, further comprising:
subsequent to plasma etching the semiconductor wafer through the scribe lines, removing the patterned mask, wherein the semiconductor wafer is further supported on the tape of the substrate carrier while removing the patterned mask.

4. The method of claim 1, wherein the scribe lines include trenches in the semiconductor wafer, between the integrated circuits, and wherein plasma etching the semiconductor wafer through the scribe lines comprises forming trench extensions corresponding to the trenches.

5. The method of claim 1, wherein the thermally resistant frame of the substrate carrier comprises polyphenylene sulfide (PPS).

6. The method of claim 1, wherein the thermally resistant frame of the substrate carrier has a thermal conductivity approximately in the range of 0.245-0.389 W/(m.K) at 25 degrees Celsius.

7. A method of dicing a semiconductor wafer comprising a front surface having a plurality of integrated circuits thereon, the method comprising:
forming a mask on the front surface of the semiconductor wafer, the mask covering the integrated circuits and streets between the integrated circuits;
laser scribing the mask and streets to provide scribe lines between the integrated circuits and to leave a patterned mask covering the integrated circuits; and
plasma etching the semiconductor wafer through the scribe lines to singulate the integrated circuits, wherein the semiconductor wafer is supported on a tape of a substrate carrier having a thermally resistant frame during the plasma etching.

8. The method of claim 7, further comprising:
subsequent to plasma etching the semiconductor wafer, expanding the tape of the substrate carrier and performing a die pick operation.

9. The method of claim 7, wherein the semiconductor wafer is further supported on the tape of the substrate carrier during the laser scribing.

10. The method of claim 9, wherein the semiconductor wafer is further supported on the tape of the substrate carrier while forming the mask.

11. The method of claim 7, further comprising:
subsequent to plasma etching the semiconductor wafer through the scribe lines, removing the patterned mask, wherein the semiconductor wafer is further supported on the tape of the substrate carrier while removing the patterned mask.

12. The method of claim 7, wherein laser scribing the mask and the streets further comprises forming trenches in the semiconductor wafer, between the integrated circuits, and wherein plasma etching the semiconductor wafer through the scribe lines comprises forming trench extensions corresponding to the trenches.

13. The method of claim 7, wherein the thermally resistant frame of the substrate carrier has a thermal conductivity approximately in the range of 0.245-0.389 W/(m.K) at 25 degrees Celsius.
